(19) United States
(12) Patent Application Publication
(10) Pub. No.: US 2025/0117540 A1
(43) Pub. Date: Apr. 10, 2025

(54) SYSTEMS AND METHODS FOR CLIMATE MODELING

(71) Applicant: Allstate Insurance Company, Northbrook, IL (US)

(72) Inventors: Andrew Young, Livingston, NJ (US); Sarah K. Webster, Wilmington, NC (US); Marvin Lu, Chicago, IL (US); Howard Hayes, Glencoe, IL (US)

(21) Appl. No.: 18/377,428

(22) Filed: Oct. 6, 2023

(51) Int. Cl. G06F 30/20

(52) U.S. Cl. CPC G06F 30/20

(57) ABSTRACT

Implementations described herein provide systems and methods for mitigating climate risk. In one implementation, an environmental forecast factor is determined based on one or more predictive climate models. The environmental forecast factor can be, for example, an environmental condition applied to a specific home. A severity of the environmental forecast factor on the specific home can be determined over a period of time. A financial instrument can be created that invests in an asset that is inversely related to the environmental forecast factor over the period of time, where the financial instrument is predicted to appreciate in value to at least the severity of the environmental forecast factor.

### FIELD

Aspects of the present disclosure relate to systems and methods for climate modeling for an area, such as a particular property, and more particular to generating mitigation actions for an area based on climate modeling.

### BACKGROUND

Climate change results in various new and evolving risks to businesses, homes, and homeowners, such as the increased risk for wildfires, flooding, increasingly powerful and violent storms, rising sea level, degradation of coastal land, extreme weather events, and/or other climate-related risks and catastrophes. These climate-related risks may take property owners by surprise, resulting in property owners experiencing loss or otherwise being unprepared.

It is with these observations in mind, among others, that aspects of the present disclosure were conceived and developed.

### SUMMARY

Implementations described and claimed herein address the foregoing by providing systems and methods for mitigating long term climate risk. In one implementation, an environmental forecast factor is determined based on one or more predictive climate models. The environmental forecast factor can be, for example, an environmental condition applied to a specific home. A severity of the environmental forecast factor on the specific home can be determined over a period of time. A financial instrument can be created that invests in an asset that is inversely related to the environmental forecast factor over the period of time, where the financial instrument is predicted to appreciate in value to at least the severity of the environmental forecast factor.

In another implementation, existing home infrastructure can be determined for the specific home based on historical data, including, without limitation, claims data, repair data, improvement data, and/or other data relating to an infrastructure or environmental history of the specific home and homes in an area associated with the specific home. The severity of the environmental forecast factor can be identified based on the environmental condition to be applied to the existing home infrastructure.

In another implementation, an amount of depreciation of the specific home can be determined based on the severity of the environmental forecast factor as applied to the existing home infrastructure.

In another implementation, a user interface can be dynamically configured to enable a user to access the environmental forecast factor for the specific home associated with a user account. Predicted home damage can be determined based on the environmental forecast factor. One or more Climate Savings Account (CSA) programs can be determined to be applicable to the predicted home damage based on the environmental forecast factor, wherein the one or more CSA programs cover the predicted home damage not covered by a current insurance policy, and a recommendation for the one or more CSA programs can be output.

In another implementation, the environmental forecast factor can be based on one or more of drought conditions or fire risk conditions, and the asset can be based on one or more of water rights or air conditioning technology.

In another implementation, a user interface can be dynamically configured to enable a user to access climate data based on the one or more predictive climate models for the specific home, where the specific home is associated with a user account. A layout can be arranged personalized to the specific home and, based at least in part on receiving an indication of an interaction with the layout, an applet corresponding to a selected service based on the financial instrument can be associated. An onboarding flow can be launched associated with the financial instrument, where the onboarding flow is customized for at least one of the user or the selected service.

In another implementation, an optimal booklet can be selected for an optimal financial instrument and for the specific home from a plurality of booklets based on the environmental forecast factor personalized to the specific home. A recommendation for the optimal booklet can be output to a device associated with a user account of the specific home, wherein the recommendation is based on educational information about the financial instrument as applied to the specific home.

In another implementation, a computing apparatus includes a processor and a memory storing instructions that, when executed by the processor, configure the apparatus to determine an environmental forecast factor based on one or more predictive climate models. The environmental forecast factor can be, for example, an environmental condition applied to a specific home. A severity of the environmental forecast factor on the specific home can be determined over a period of time. A financial instrument can be created that invests in an asset that is inversely related to the environmental forecast factor over the period of time, where the financial instrument is predicted to appreciate in value to at least the severity of the environmental forecast factor.

In another implementation, a non-transitory computer-readable storage medium includes instructions that, when executed by a computer, cause the computer to determine an environmental forecast factor based on one or more predictive climate models. The environmental forecast factor can be, for example, an environmental condition applied to a specific home. A severity of the environmental forecast factor on the specific home can be determined over a period of time. A financial instrument can be created that invests in an asset that is inversely related to the environmental forecast factor over the period of time, wherein the financial instrument is predicted to appreciate in value to at least the severity of the environmental forecast factor.

Other implementations are also described and recited herein. Further, while multiple implementations are disclosed, still other implementations of the presently disclosed technology will become apparent to those skilled in the art from the following detailed description, which shows and describes illustrative implementations of the presently disclosed technology. As will be realized, the presently disclosed technology is capable of modifications in various aspects, all without departing from the spirit and scope of the presently disclosed technology. Accordingly, the drawings and detailed description are to be regarded as illustrative in nature and not limiting.

### BRIEF DESCRIPTION OF THE DRAWINGS

FIG. 1 illustrates an example environment for a climate risk mitigation in accordance with some examples.

FIG. 2 is a flow diagram illustrating a climate mitigation personalization process in accordance with some examples.

FIG. 3 is an example computing system that may implement various systems and methods discussed herein.

### DETAILED DESCRIPTION

Aspects of the presently disclosed technology generally relate to systems and methods for mitigating long term climate risk to property on a geographic scale personalized to the land topography, atmospheric conditions, and/or bodies of water or other features that affect climate-related hazard risks. The various systems and methods disclosed herein generally provide for risk awareness and prevention of climate hazards, such that a user can learn about risks personalized to their property and available solutions to mitigate that risk. In some examples, the systems and methods disclosed herein provide a user the ability to understand the risks their property faces in the evolving changes to their local climate (e.g., predicted risks that deviate from historical climate patterns), understand the severity of property depreciation as a result of the risks, understand available solutions and options, evaluate options and tradeoffs of investing in assets to offset predicted property depreciation, and the predicted costs of climate mitigating protections as applied to their home.

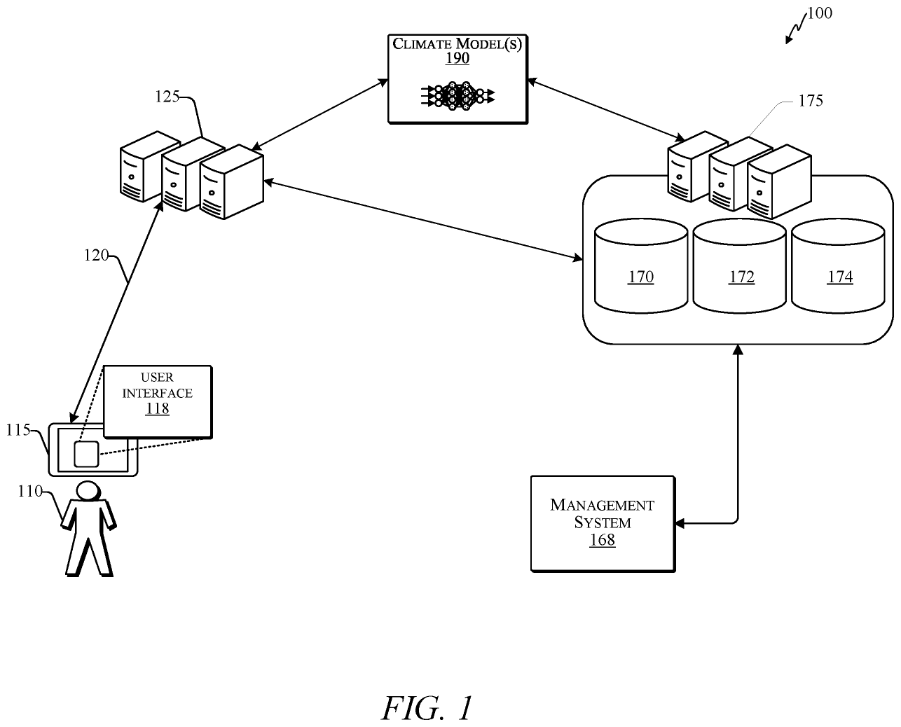

To begin a detailed description of an example environment 100 for mitigating long-term climate risk for an area (e.g., particular property of a user), reference is made to FIG. 1. In one implementation, the example environment 100 includes a climate risk advisor 125 that determines an environmental forecast factor based on an output of one or more predictive climate models 190. The environmental forecast factor can be, in some implementations, an environmental condition applied to a specific area (e.g., home).

In many cases, climate hazards carry a spatial context. While climate is normally thought of as weather conditions prevailing in an area in general or over a long period (e.g., the composite of long-term pattern of weather in a particular area), the weather conditions themselves that arise from climate conditions—e.g., the climate hazards—manifest locally. The direct impacts of physical climate risk thus need to be understood in the context of a geographically defined area, the size of which needs to be determined by contextual factors. There are many variations between the relationship between atmospheric conditions, land topography, and/or bodies of water that impact the risk of specific climate hazards to each spatial context.

As the Earth continues to warm, physical climate risk is ever-changing and non-stationary. Further warming is likely to remain a risk factor for at least the next decade because of physical inertia in the geophysical system. Furthermore, given the thermal inertia of the earth system, some amount of warming will also continue to occur even if net-zero emissions are reached. Socioeconomic impacts are likely to propagate in a nonlinear way as hazards reach thresholds beyond which the affected physiological, human-made, or ecological systems work less well or break down and stop working altogether. Because such systems have evolved or been optimized over time for historical climates, the climate-related risks will have a nonlinear effect on property owners. Moreover, while the direct impact from climate change is spatially local, it can have knock-on effects across regions and sectors through interconnected socioeconomic and financial systems. Property owners will need assistance with understanding climate risks as applied to their personal property, such as the evolving risks they will face, building alternate means for generating financial resources to hedge against that risk, and understanding available solutions and options for recouping the loss of a property's valuation.

In some examples, the climate risk advisor 125 can determine a severity of the environmental forecast factor on the specific home over a period of time, and then an asset service 172 within a risk processing service 175 can create one or more instruments that invest in an asset that is inversely related to the environmental forecast factor over the period of time. In some implementations, the instrument is predicted to appreciate in value relative to at least the severity of the environmental forecast factor.

Techniques and systems for providing a climate risk advisor 125, which can be a service/tool that provides a module and/or application that calculates a property's risk scores based on the various environmental peril risks (e.g., flood, wildfire, wind, heat, etc.) that homeowners and/or buyers face as a result of climate change. In some implementations, the climate risk advisor 125 can provide resources to prepare the user for property losses or depreciation as a result of climate change (e.g., a climate change risk hedge and/or a climate savings account).

In at least one example, the climate risk advisor 125 provides a service (e.g., insurance for climate risks, investment services to hedge against climate change risks, home infrastructure services) and/or product education, onboarding and/or upselling can be accomplished through a personalized onboarding page for new users and/or a personalized user interface for existing users based on various predictive climate models 190. The climate models 190 may analyze contextual information about a user's property as well as claims filed by existing customers for home infrastructure information (e.g., strengthening a home against rising climate-related risks). Depending on various environmental forecast factors determined by the climate models 190, a financial instrument that can hedge against climate-related property value losses can be generated and selected and displayed within the user interface of a user's device, unlocking an ability to educate new customers about their personalized climate related risks and boosting engagements in certain mitigating financial assets that balance the risk in depreciating property values.

In some implementations, the climate risk advisor 125 can increase user engagement along the sales funnel to improve user rates and retention for newly evolving protection needs related to climate change. For example, the climate risk advisor 125 can additionally and/or alternatively offer the asset service 172 that can help homeowners understand available assets for investment. A user may balk at the prospect of using asset investments until they gain more confidence in their understanding of the subject (e.g., its specific risks and benefits, particular strengths and trends of each type of asset, etc.), and how the asset can mitigate climate risk to their specific property. The asset service 172 can offer various features that can help them apply and manage the investment process. The asset could be risk hedging investments, for example, that provide an inverse return on investment for latent and/or post-catastrophe situations including loss of value to the home due to rebuilding and repairing the home. In some implementations, the investments can be selected from assets included in management system 168 (which may host an application, web page, etc.).

Moreover, in some implementations, the risk processing service 175 can include a climate savings account 174 that can provide a streamlined response for applying to a savings account specifically related to personalized climate risks by pre-filling part or all of a climate savings account application. The climate savings account 174 can, for example, be a product that allows users to add money (for example, pre-tax) to the climate savings account 174 account to help pay for deductibles or any home-related damages not covered in their policy that occur in the future from a catastrophe. Information used to pre-fill the climate savings application can, for example, be pulled from user information stored in user account(s) 170.

The techniques and systems for a financial service offering that are described herein additionally and/or alternatively include an interactive user interface element that is generated and used for facilitating climate risk hedging personalized to a user's property and/or for presenting the asset service 172 and/or climate savings account 174. In at least one example, the interactive element can be selected and displayed within the user interface in a dynamic, personalized way based on one or more climate models 190 designed for predicting each customer's property risk as applied to their predicted climate risks (e.g., an environmental forecast factor), the property's severity of risk and predicted deprecation in value, and future profit associated with a financial asset or service being offered. The climate risk advisor 125 can analyze contextual information about the user during or after the customer onboarding stage to select the top financial product for offering or upselling at those stages. The top financial product, for example, can be selected by ranking an expected profit from each <customer, asset>pair and selecting the asset with the highest projected value increase over the time the user's property is projected to be at risk. The climate risks to a user's home can then be displayed on the interactive user interface, as well as any related financial assets or services to help the user mitigate their personalized risk metrics. Additionally and/or alternatively, if further education on the risks, its impact(s), and/or financial services are needed, one or more recommendation models within climate risk advisor 125 can predict a customer's likelihood of clicking on a specific climate-related booklet, can rank a list of booklets, and then select one or more booklets for dynamic, personalized booklet arrangements within a user interface. The booklet can, for example, explain the assets being offered by the financial management resource 168, its projected value in relation to the climate-related risks faced by the user 110, and any other relevant information.

Techniques and systems described herein describe generating an environmental forecast factor based on a predictive analysis by climate models 190. A risk metric and/or an associated value metric (e.g., the precited loss in value of the user's property as a result of changing climate effects) can be determined for the user based on a combination of contextual information within the risk processing service 175 and the environmental forecast factor output from the climate model(s) 190.

In some implementations, the climate model(s) 190 can be numerical models that generate climate predictions based on physical parameterizations of key atmospheric processes. For example, the climate model(s) 190 can be non-hydrostatic models that can be used to study both small-scale and large-scale processes-such as physical phenomena with sizes ranging from meters to 10,000 km or more. In some implementations, the climate model(s) 190 can simulate atmospheric conditions by including a non-hydrostatic formulation that includes the full vertical momentum equation and requires the solution of 3-D elliptic equations for non-hydrostatic pressure perturbation. In some implementations, finite volume techniques can be employed yielding an intuitive discretization and support for the treatment of irregular geometries, such as through the use of orthogonal curvilinear grids and/or shaved cells.

In some implementations, after applying the environmental forecast factor to a specific home associated with user account 170, the climate risk advisor 125 can determine one or more effects of an environmental forecast factor on the specific home over a period of time. The climate risk advisor 125 can then determine and then recommend a financial product or asset (such as an investment asset) personalized to the specific home based on the environmental forecast factor. For example, the user 110 may have a home located in an area that, based on predicted climate change conditions for the relevant specific geographic area output from the climate model(s) 190, puts the home at an increased risk for fire at a certain rate over a period of time. This risk is above the historical risk linked to the area's past climate weather patterns. The climate risk advisor 125 can, for example, personalize the accuracy of the climate model(s) 190 prediction by determining an appropriate range for climate predictions, such as determining a bounding box that includes the home and geographic features that affect climate, such as mountain ranges, oceans, rivers, topography relief that impacts wind patterns, or any other topography features that provides climate context. For example, the user's 110 home may be located in a rift valley surrounded on one side by a mountain range. The climate risk advisor 125 can determine a bounding area that includes the rift valley and the mountain range, as those topology features would increase rainfall on one side of the mountain beyond the average of the area in general but decrease the amount of rainfall on the other side. Based on the environmental forecast factor of increased fire risk at the certain rate, the climate risk advisor 125 can identify one or more mitigating actions that mitigates the risk factor—for example, offering investments in water rights or air conditioning technology as the weather increases in temperature. Therefore, the investments offered can lessen a severity of the environmental forecast factor.

A user interface 118 (e.g., application, webpage, etc.) can be dynamically configured on a user device 115, based on the environmental forecast factor (or multiple environmental forecast factors), to enable the user 110 to access information about climate risks to a property associated with a user account 170. In some implementations, the user interface 118 can present the identified mitigating financial assets/investments that would provide hedging for the user's 110 home. For example, the user interface 118 can include a layout that is arranged personalized to the specific home. The layout can include property risk information 120, such as the climate risks identified by the climate model(s) 190, predicted costs associated with the environmental forecast factor if left unprotected, and mitigating financial services/assets provided financial management resource 168.

In some implementations, the user interface 118 can arrange tiles on the user interface 118 to personalize a layout to the user 110. Each tile can represent certain climate-related environmental forecast factors particular to a property (such as a home) of the user 110. The tiles may correspond to an applet or booklet personalized for the user. In some implementations, the booklet includes content particular to the environmental forecast factor and/or an available climate savings account 174 the user 110 can make payments in preparation for future risk to their home. In some implementations, the applet can be associated with content related to the identified risk to the home and a selected investment, asset, or other financial service with which the risk can be mitigated, and which can then be displayed on the user interface 118. Based on receiving an indication of an interaction with the tile, an onboarding flow associated with the selected service can be launched. The onboarding flow can be customized for the user 110, the selected investment, asset, or other financial product or service, or all.

In some examples, the risk processing service 175 can determine existing home infrastructure for the specific home based on historical data, such as claims data from claims service 174. The existing home infrastructure information can be linked to the user account 170 and can further personalize the climate risk advisor's 125 predictions of climate-related risks via the environmental forecast factor to the user's 110 home.

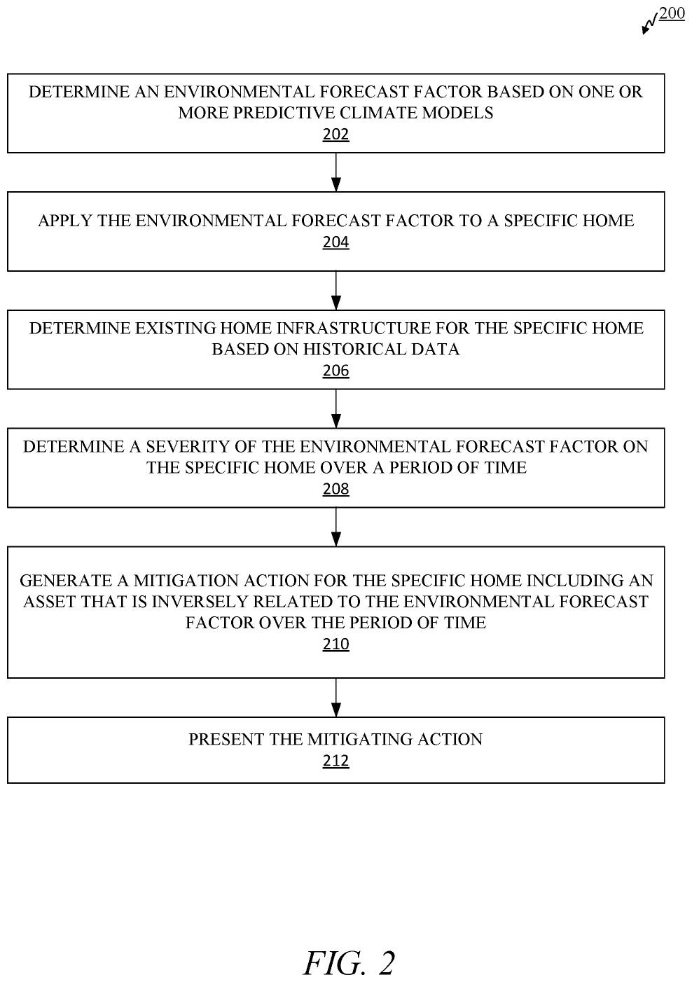

Referring to FIG. 2, example operations 200 for climate mitigation personalization process are shown. It will be appreciated, however, that the operations 200 may be applied in contexts involving other types of climate and personal data, applications, and services. In one implementation, an operation 202 can determine an environmental forecast factor based on one or more predictive climate models. The environmental forecast factor can be, for example, an environmental condition applied to a specific area (e.g., a specific home). In some example implementations, the environmental forecast factor can be, but is not limited to, one or more of drought conditions, fire risk, flooding risk, severe wind and/or storm risk, etc. At operation 204, the environmental forecast factor can be applied to the specific home.

For example, the environmental forecast factor can be expressed as a risk metric and/or an associated value metric (e.g., the predicted loss in value of the user's property as a result of changing climate effects), which can be determined for the user based on a combination of contextual information within the risk processing service 175 and the output(s) of climate model(s) 190. The environmental forecast factor can be based on changing weather patterns and/or features, and/or the results of the changing weather patterns, such as increased heat, rainfall, severity of storms or wind, flooding, fire, mudslides, worsening erosion of land, etc.

In some implementations, contextual information about the specific home can be determined, such as existing structures or features in, on, and/or around the home that can affect the accuracy of the predictive climate models. For example, in one implementation, an operation 206 can determine existing home infrastructure for the specific home based on one or more claims data. For example, the home may have already existing reinforced foundations, drainage features, fire breaks, etc.

An operation 208 can determine a severity of the environmental forecast factor on the specific home over a period of time. Based on the environmental forecast factor determined by the one or more predictive climate models, operation 210 can generate a mitigation action (e.g., a financial instrument, property change, etc.) that involves an asset that is inversely related to the environmental forecast factor over the period of time. In some implementations, the severity of the environmental forecast factor can be identified based on the environmental condition as applied to the existing home infrastructure. In some implementations, an amount of depreciation of the specific home can be determined based on the severity of the environmental forecast factor as applied to the existing home infrastructure.

An operation 212 presents the mitigating action, such as presenting the mitigating action through a user interface. For example, the climate risk advisor 125 can create a financial instrument that invests in an asset that is inversely related to the environmental forecast factor over the relevant period of time, where the financial instrument is predicted to appreciate in value to at least the severity of the environmental forecast factor. The financial instrument can be an asset that is based on, but not limited to, water rights, lumber rights, air conditioning or heating technology, etc.

In some implementations, a user interface can be dynamically configured to enable a user access to climate data based on the one or more predictive climate models for the specific home, where the specific home is associated with a user account. A layout can be arranged on the user interface that is personalized to the specific home. Based at least in part on receiving an indication of an interaction with the layout, an applet corresponding to a selected service can be associated based on the financial instrument, and an onboarding flow associated with the financial instrument can be launched on the user interface, where the onboarding flow is customized for at least one of the user or the selected service.

In some implementations, an optimal booklet can be selected for an optimal financial instrument and for the specific home from a plurality of booklets based on the environmental forecast factor personalized to the specific home. A recommendation can be output for the optimal booklet to a device associated with a user account of the specific home, where the recommendation is based on educational information about the financial instrument as applied to the specific home.

In some implementations, a user interface can be dynamically configured to enable a user to access the environmental forecast factor for the specific home associated with a user account. An amount of predicted home damage can be determined based on the environmental forecast factor. One or more Climate Savings Account (CSA) programs applicable to the predicted home damage can be determined and selected for the user based on the environmental forecast factor, where the one or more CSA programs cover the predicted home damage not covered by a current insurance policy. A recommendation for the one or more CSA programs can be output to the user interface and/or user device.

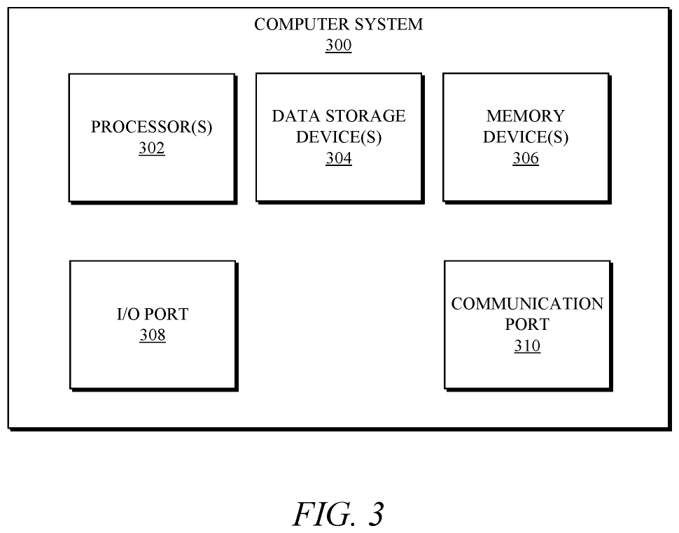

Referring to FIG. 3, a detailed description of an example computing system 300 having one or more computing units that may implement various systems and methods discussed herein is provided. The computing system 300 may be applicable to various devices in the environment 100, such as the user device 115, the climate risk advisor 125, the risk processing service 175 (including each of the sub-components and systems), and/or other computing or network devices. It will be appreciated that specific implementations of these devices may be of differing possible specific computing architectures not all of which are specifically discussed herein but will be understood by those of ordinary skill in the art.

The computer system 300 may be a computing system that is capable of executing a computer program product to execute a computer process. Data and program files may be input to the computer system 300, which reads the files and executes the programs therein. Some of the elements of the computer system 300 are shown in FIG. 3, including one or more hardware processors 302, one or more data storage devices 304, one or more memory devices 308, and/or one or more ports 308-310. Additionally, other elements that will be recognized by those skilled in the art may be included in the computing system 300 but are not explicitly depicted in FIG. 3 or discussed further herein. Various elements of the computer system 300 may communicate with one another by way of one or more communication buses, point-to-point communication paths, or other communication means not explicitly depicted in FIG. 3.

The processor 302 may include, for example, a central processing unit (CPU), a microprocessor, a microcontroller, a digital signal processor (DSP), and/or one or more internal levels of cache. There may be one or more processors 302, such that the processor 302 comprises a single central-processing unit, or a plurality of processing units capable of executing instructions and performing operations in parallel with each other, commonly referred to as a parallel processing environment.

The computer system 300 may be a conventional computer, a distributed computer, or any other type of computer, such as one or more external computers made available via a cloud computing architecture. The presently described technology is optionally implemented in software stored on the data stored device(s) 304, stored on the memory device(s) 306, and/or communicated via one or more of the ports 308-310, thereby transforming the computer system 300 in FIG. 3 to a special purpose machine for implementing the operations described herein. Examples of the computer system 300 include personal computers, terminals, workstations, mobile phones, tablets, laptops, personal computers, multimedia consoles, gaming consoles, set top boxes, and the like.

The one or more data storage devices 304 may include any non-volatile data storage device capable of storing data generated or employed within the computing system 300, such as computer executable instructions for performing a computer process, which may include instructions of both application programs and an operating system (OS) that manages the various components of the computing system 300. The data storage devices 304 may include, without limitation, magnetic disk drives, optical disk drives, solid state drives (SSDs), flash drives, and the like. The data storage devices 304 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 306 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 304 and/or the memory devices 306, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 300 includes one or more ports, such as an input/output (I/O) port 308 and a communication port 310, for communicating with other computing, network, or vehicle devices. It will be appreciated that the ports 308-310 may be combined or separate and that more or fewer ports may be included in the computer system 300.

The I/O port 308 may be connected to an I/O device, or other device, by which information is input to or output from the computing system 300. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 300 via the I/O port 308. Similarly, the output devices may convert electrical signals received from computing system 300 via the I/O port 308 into signals that may be sensed as output by a human, such as sound, light, and/or touch. The input device may be an alphanumeric input device, including alphanumeric and other keys for communicating information and/or command selections to the processor 302 via the I/O port 308. The input device may be another type of user input device including, but not limited to: direction and selection control devices, such as a mouse, a trackball, cursor direction keys, a joystick, and/or a wheel; one or more sensors, such as a camera, a microphone, a positional sensor, an orientation sensor, a gravitational sensor, an inertial sensor, and/or an accelerometer; and/or a touch-sensitive display screen (“touchscreen”). The output devices may include, without limitation, a display, a touchscreen, a speaker, a tactile and/or haptic output device, and/or the like. In some implementations, the input device and the output device may be the same device, for example, in the case of a touchscreen.

The environment transducer devices convert one form of energy or signal into another for input into or output from the computing system 300 via the I/O port 308. For example, an electrical signal generated within the computing system 300 may be converted to another type of signal, and/or vice-versa. In one implementation, the environment transducer devices sense characteristics or aspects of an environment local to or remote from the computing device 300, such as, light, sound, temperature, pressure, magnetic field, electric field, chemical properties, physical movement, orientation, acceleration, gravity, and/or the like. Further, the environment transducer devices may generate signals to impose some effect on the environment either local to or remote from the example computing device 300, such as, physical movement of some object (e.g., a mechanical actuator), heating or cooling of a substance, adding a chemical substance, and/or the like.

In one implementation, a communication port 310 is connected to a network by way of which the computer system 300 may receive network data useful in executing the methods and systems set out herein as well as transmitting information and network configuration changes determined thereby. Stated differently, the communication port 310 connects the computer system 300 to one or more communication interface devices configured to transmit and/or receive information between the computing system 300 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 310 to communicate one or more other machines, either directly over a point-to-point communication path, over a wide area network (WAN) (e.g., the Internet), over a local area network (LAN), over a cellular (e.g., third generation (3G) or fourth generation (4G)) network, or over another communication means. Further, the communication port 310 may communicate with an antenna or other link for electromagnetic signal transmission and/or reception.

In an example implementation, climate modeling and mitigation software and other modules and services may be embodied by instructions stored on the data storage devices 304 and/or the memory devices 306 and executed by the processor 302.

The system set forth in FIG. 3 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

In the present disclosure, the methods disclosed may be implemented as sets of instructions or software readable by a device. Further, it is understood that the specific order or hierarchy of steps in the methods disclosed are instances of example approaches. Based upon design preferences, it is understood that the specific order or hierarchy of steps in the method can be rearranged while remaining within the disclosed subject matter. The accompanying method claims present elements of the various steps in a sample order and are not necessarily meant to be limited to the specific order or hierarchy presented.

The described disclosure may be provided as a computer program product, or software, that may include a non-transitory machine-readable medium having stored thereon instructions, which may be used to program a computer system (or other electronic devices) to perform a process according to the present disclosure. A machine-readable medium includes any mechanism for storing information in a form (e.g., software, processing application) readable by a machine (e.g., a computer). The machine-readable medium may include, but is not limited to, magnetic storage medium, optical storage medium; magneto-optical storage medium, read only memory (ROM); random access memory (RAM); erasable programmable memory (e.g., EPROM and EEPROM); flash memory; or other types of medium suitable for storing electronic instructions.

While the present disclosure has been described with reference to various implementations, it will be understood that these implementations are illustrative and that the scope of the present disclosure is not limited to them. Many variations, modifications, additions, and improvements are possible. More generally, implementations in accordance with the present disclosure have been described in the context of particular implementations. Functionality may be separated or combined in blocks differently in various implementations of the disclosure or described with different terminology. These and other variations, modifications, additions, and improvements may fall within the scope of the disclosure as defined in the claims that follow.

What is claimed is:

1. A method for mitigating climate risk, the method comprising:
determining an environmental forecast factor based on one or more predictive climate models, the environmental forecast factor being an environmental condition applied to a specific home;
determining a severity of the environmental forecast factor on the specific home over a period of time; and
generating a mitigation action for the specific home, the mitigation action including an asset that is inversely related to the environmental forecast factor over the period of time.

2. The method of claim 1, the method further comprising:
determining existing home infrastructure for the specific home based on historical data; and
identifying the severity of the environmental forecast factor based on the environmental condition to be applied to the existing home infrastructure.

3. The method of claim 2, the method further comprising:
determining an amount of depreciation of the specific home based on the severity of the environmental forecast factor as applied to the existing home infrastructure.

4. The method of claim 1, the method further comprising:
dynamically configuring a user interface to enable a user to access the environmental forecast factor for the specific home associated with a user account;
determining predicted home damage based on the environmental forecast factor;
determining one or more climate programs applicable to the predicted home damage based on the environmental forecast factor, wherein the one or more climate programs cover the predicted home damage; and
outputting a recommendation for the one or more climate programs.

5. The method of claim 1, wherein the environmental forecast factor is based on at least one of drought conditions or fire risk conditions, and the asset is based on at least one of water rights or air conditioning technology.

6. The method of claim 1, the method further comprising:
dynamically configuring a user interface to enable a user access to climate data based on the one or more predictive climate models for the specific home, wherein the specific home is associated with a user account; and
arranging a layout personalized to the specific home;
based at least in part on receiving an indication of an interaction with the layout, associating an applet corresponding to a selected service based on the mitigation action; and
launching an onboarding flow associated with the mitigation action, wherein the onboarding flow is customized for at least one of the user or the selected service.

7. The method of claim 1, the method further comprising:
selecting an optimal booklet for an optimal instrument and for the specific home from a plurality of booklets based on the environmental forecast factor personalized to the specific home; and
outputting a recommendation for the optimal booklet to a device associated with a user account of the specific home, wherein the recommendation is based on educational information about the instrument as applied to the specific home.

8. A computing apparatus comprising:
a processor; and
a memory storing instructions that, when executed by the processor, configure the computing apparatus to:
determine an environmental forecast factor based on one or more predictive climate models, the environmental forecast factor being an environmental condition applied to a specific home;
determine a severity of the environmental forecast factor on the specific home over a period of time; and
generate a mitigation action for the specific home, the mitigation action including an asset that is inversely related to the severity of the environmental forecast factor over the period of time.

9. The computing apparatus of claim 1, wherein the instructions further configure the computing apparatus to:
determine existing home infrastructure for the specific home based on historical data; and
identify the severity of the environmental forecast factor based on the environmental condition to be applied to the existing home infrastructure.

10. The computing apparatus of claim 2, wherein the instructions further configure the computing apparatus to:
determine an amount of depreciation of the specific home based on the severity of the environmental forecast factor as applied to the existing home infrastructure.

11. The computing apparatus of claim 1, the method wherein the instructions further configure the computing apparatus to:
dynamically configure a user interface to enable a user access to the environmental forecast factor for the specific home associated with a user account;
determine predicted home damage based on the environmental forecast factor;
determine one or more climate programs applicable to the predicted home damage based on the environmental forecast factor, wherein the one or more climate programs cover the predicted home damage; and
output a recommendation for the one or more climate programs.

12. The computing apparatus of claim 1, wherein the environmental forecast factor is based on at least one of drought conditions or fire risk conditions, and the asset is based on at least of water rights or air conditioning technology.

13. The computing apparatus of claim 1, wherein the instructions further configure the computing apparatus to:
dynamically configure a user interface to enable a user access to climate data based on the one or more predictive climate models for the specific home, wherein the specific home is associated with a user account; and
arrange a layout personalized to the specific home;
based at least in part on receiving an indication of an interaction with the layout, associate an applet corresponding to a selected service based on the asset; and
launch an onboarding flow associated with the asset, wherein the onboarding flow is customized for at least one of the user or the selected service.

14. The computing apparatus of claim 1, wherein the instructions further configure the computing apparatus to:
select an optimal booklet for an optimal instrument and for the specific home from a plurality of booklets based on the environmental forecast factor personalized to the specific home; and
output a recommendation for the asset in the form of the optimal booklet to a device associated with a user account of the specific home, wherein the recommendation is based on educational information about the instrument as applied to the specific home.

15. A non-transitory computer-readable storage medium, the non-transitory computer-readable storage medium including instructions that when executed by a computer, cause the computer to:
determine an environmental forecast factor based on one or more predictive climate models, the environmental forecast factor being an environmental condition applied to a specific area;
determine a severity of the environmental forecast factor on the specific area over a period of time; and
generate a mitigation action for the specific area that is inversely related to the severity of the environmental forecast factor over the period of time.

16. The non-transitory computer-readable storage medium of claim 1, wherein the instructions further configure the computer to:
determine existing infrastructure for the specific area based on historical data; and
identify the severity of the environmental forecast factor based on the environmental condition to be applied to the existing infrastructure.

17. The non-transitory computer-readable storage medium of claim 2, wherein the instructions further configure the computer to:
determine an amount of depreciation of the specific area based on the severity of the environmental forecast factor as applied to the existing infrastructure.

18. The non-transitory computer-readable storage medium of claim 1, wherein the specific area is a specific home, the instructions further configure the computer to:
dynamically configure a user interface to enable the user to access the environmental forecast factor for the specific home associated with a user account;
determine predicted home damage based on the environmental forecast factor;
determine one or more climate programs applicable to the predicted home damage based on the environmental forecast factor, wherein the climate programs cover the predicted home damage; and
output a recommendation for the one or more climate programs.

19. The non-transitory computer-readable storage medium of claim 1, wherein the environmental forecast factor is based on at least one of drought conditions or fire risk conditions, and the asset is based on at least of water rights or air conditioning technology.

20. The non-transitory computer-readable storage medium of claim 1, wherein the specific area is a specific home, the instructions further configure the computer to:
dynamically configure a user interface to enable the user access to climate data based on the one or more predictive climate models for the specific home, wherein the specific home is associated with a user account; and
arrange a layout personalized to the specific home;
based at least in part on receiving an indication of an interaction with the layout, associate an applet corresponding to a selected service based on the asset; and
launch an onboarding flow associated with the asset, wherein the onboarding flow is customized for at least one of the user or the selected service.
